(19) United States
(12) Patent Application Publication
(10) Pub. No.: US 2024/0321882 A1
(43) Pub. Date: Sep. 26, 2024

(54) DIFFERENT WORK FUNCTION METALS

(71) Applicant: INTERNATIONAL BUSINESS MACHINES CORPORATION, Armonk, NY (US)

(72) Inventors: Soon-Cheon Seo, Glenmont, NY (US); Ruqiang Bao, Niskayuna, NY (US); Min Gyu Sung, Latham, NY (US)

(21) Appl. No.: 18/189,411

(22) Filed: Mar. 24, 2023

(51) Int. Cl. H01L 27/092; H01L 21/28; H01L 21/8238; H01L 29/06; H01L 29/423; H01L 29/49; H01L 29/66; H01L 29/775

(52) U.S. Cl. CPC H01L 27/092; H01L 21/28088; H01L 21/823807; H01L 21/823842; H01L 29/0673; H01L 29/42392; H01L 29/4908; H01L 29/66439; H01L 29/66545; H01L 29/775

(57) ABSTRACT

Within a replacement gate structure, there a first channel cell that includes one or more first channels that are associated with a first transistor device (e.g., a nFET transistor) and a second channel cell that includes one or more second channels that are associated with a second transistor device (e.g., a pFET transistor). A first work function (WF) gate is around the one or more first channels and a second WF gate is around the one or more second channels. In alternative implementations, the replacement gate structure may include separate instances of a replacement gate upon the first WF gate and upon the second WF gate or a shared replacement gate upon both the first WF gate and upon the second WF gate. A gate contact may contact the shared replacement gate or may contact both instances of the replacement gate.

### BACKGROUND

The present disclosure relates to fabrication methods and resulting structures for semiconductor integrated circuit (IC) devices. More specifically, the present disclosure relates to fabrication methods and resulting structures of forming different work function conductors (e.g., metals, or the like) within a replacement gate structure.

In certain semiconductor IC device fabrication processes, many semiconductor IC devices, such as n-type field effect transistors (nFETs) and p-type field effect transistors (pFETs), may be fabricated on a single wafer. Non-planar transistor device architectures (e.g., fin-type FETs (FinFETs), gate all around (GAA) FETs, nanowire FETs, nanosheet FETs, or the like) can provide increased device density and increased performance over planar transistors. As semiconductor integrated circuits (ICs) and/or chips become smaller, the implementation of nanosheet, nanoribbon, or nanowire channels in semiconductor IC devices has increased. Nanosheets generally refer to multi-stacked two-dimensional nanostructures with a thickness range on the order of about 1 nanometer (nm) to about 100 nm, and they can serve as FET channels and facilitate the fabrication of non-planar semiconductor IC devices having a reduced footprint compared to conventional planar-type semiconductor IC devices. For example, nanosheet transistors, in contrast to conventional planar FETs, include a gate stack that wraps around the full perimeter of multiple stacked nanosheet channels for a reduced device footprint and improved control of channel current flow. Nanosheet transistor configurations may enable fuller depletion in the nanosheet channel regions and reduce short-channel effects. Accordingly, nanosheet transistors are seen as feasible options for CMOS technology at 3 nm node and beyond.

### SUMMARY

In an embodiment of the present disclosure, a semiconductor IC device is presented. The semiconductor IC device includes a p-type transistor and a n-type transistor. The p-type transistor includes a first plurality of nanosheets surrounded by a first work function (WF) gate and has a first vertical WF gate portion. The n-type transistor includes a second plurality of nanosheets surrounded by a second WF gate and has a second vertical WF gate portion adjacent to the first vertical WF gate portion at a junction between the p-type transistor and the n-type transistor. The semiconductor IC device further includes a common gate upon the first WF gate and upon the second WF gate.

In an embodiment of the present disclosure, another semiconductor IC device is presented. The semiconductor IC device includes a first plurality of nanosheets surrounded by a first work (WF) gate and has a first vertical WF gate portion. The semiconductor IC device further includes a second plurality of nanosheets surrounded by a second WF and has a second vertical WF gate portion. The semiconductor IC device further includes a vertical high-k layer in contact with and between the first vertical WF gate portion and the second vertical WF gate portion. The semiconductor IC device further includes a first conductive gate upon the first WF gate and a second conductive gate upon the second WF gate.

In another embodiment of the present disclosure, a replacement gate structure within a gate spacer is presented. The replacement gate structure includes a first high-K layer that has a first vertical high-k portion and a first channel high-portion that is around one or more first channel(s) that are covered by the replacement gate structure. The replacement gate structure includes a second high-K layer that has a second vertical high-K portion connected to the first vertical high-K portion and a second channel high-K portion around one or more second channel(s) that are covered by the replacement gate structure. The replacement gate structure includes a first work (WF) gate upon the first high-k layer and a second WF gate upon the second high-K layer.

The above summary is not intended to describe each illustrated embodiment or every implementation or example of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 through FIG. 12 depict various fabrication structure views of an exemplary semiconductor IC device that includes relatively different work function conductors within a replacement gate structure, according to embodiments.

FIG. 13 depicts a method of fabricating a semiconductor IC device that includes relatively different work function conductors within a replacement gate structure, according to embodiments.

FIG. 14 through FIG. 18 depict various fabrication structure views of an exemplary semiconductor IC device that includes relatively different work function conductors within a replacement gate structure, according to embodiments.

FIG. 19 depicts a method of fabricating a semiconductor IC device that includes relatively different work function conductors within a replacement gate structure, according to embodiments.

FIG. 20 through FIG. 22 depict various fabrication structure views of an exemplary semiconductor IC device that includes relatively different work function conductors within a replacement gate structure, according to embodiments.

FIG. 23 depicts a method of fabricating a semiconductor IC device that includes relatively different work function conductors within a replacement gate structure, according to embodiments.

### DETAILED DESCRIPTION

The present disclosure describes an exemplary IC device that includes a field effect transistor (FET) with a replacement gate structure. The replacement gate structure includes a first channel cell that includes one or more first channels that are associated with a first transistor device (e.g., a nFET transistor) and a second channel cell that includes one or more second channels that are associated with a second transistor device (e.g., a pFET transistor). A first work function (WF) gate is around the one or more first channels and a second WF gate is around the one or more second channels. In one implementation, the replacement gate structure may include separate instances of replacement gate conductor upon the first WFM and upon the second WFM. A gate contact may be formed upon both of the two discrete replacement gate conductors. In another implementation, the replacement gate structure may include a common instance of replacement gate conductor upon both the first WFM and the second WFM.

The flowcharts, top-down diagrams, and cross-sectional diagrams in the drawings illustrate methods of fabricating a semiconductor IC device, such as a processor, field programmable gate array (FPGA), memory module, or the like, according to various embodiments. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawings. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor IC devices are well known and so, in the interest of brevity, many conventional steps will only be mentioned briefly herein or will be omitted entirely without providing the well-known process details.

In general, the various processes used to form a microchip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a GAA nanosheet FET provides a relatively small FET footprint by forming the channel region as a series of nanosheets. In a known GAA configuration, a nanosheet GAA FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In alternative implementations, as depicted, the channel nanosheet of a p-type FET can be Si, and the sacrificial nanosheets can be SiGe.

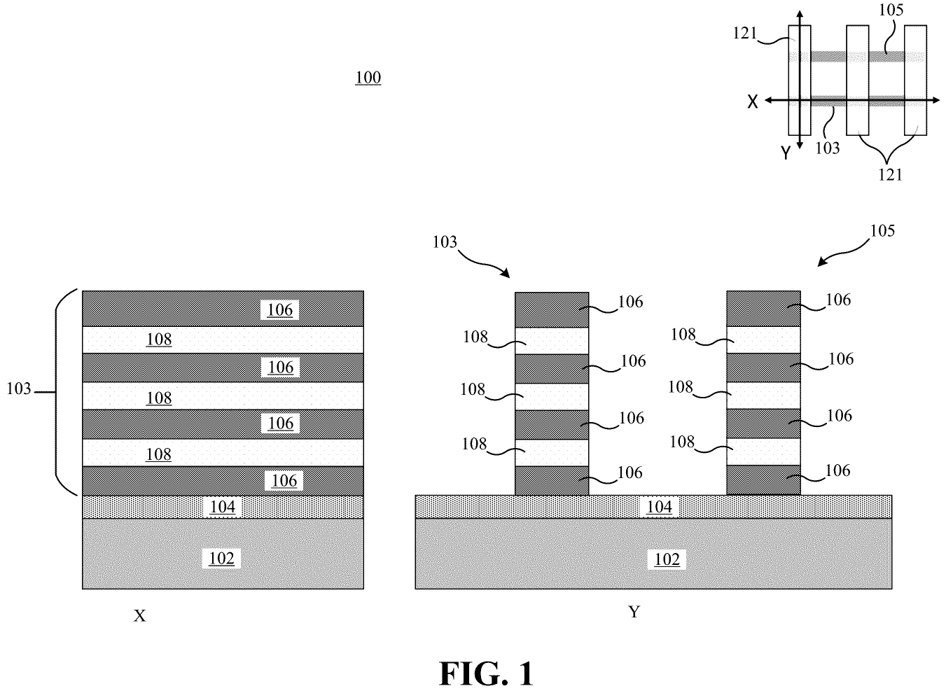

Referring now to the drawings in which like numerals represent the same or similar elements and initially to FIG. 1, this figure depicts a top-down view and cross-sectional views of a semiconductor IC device 100 at an intermediate stage of the fabrication process, according to embodiments.

The semiconductor IC device 100 may be formed over a substrate structure. The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements. In another implementation, as depicted, the substrate structure includes a substrate 102 and an insulator layer 104. The substrate 102 may be comprised of any other suitable material(s) that those listed above and the insulator layer 104 may be a dielectric layer, such as an oxide, and may be referred to as a buried oxide (BOX) layer. The dielectric layer may be any suitable dielectric, oxide, or the like, and it may adequately electrically isolate the IC microdevices (e.g., nanosheet FET(s), or the like) from the bottom substrate 102.

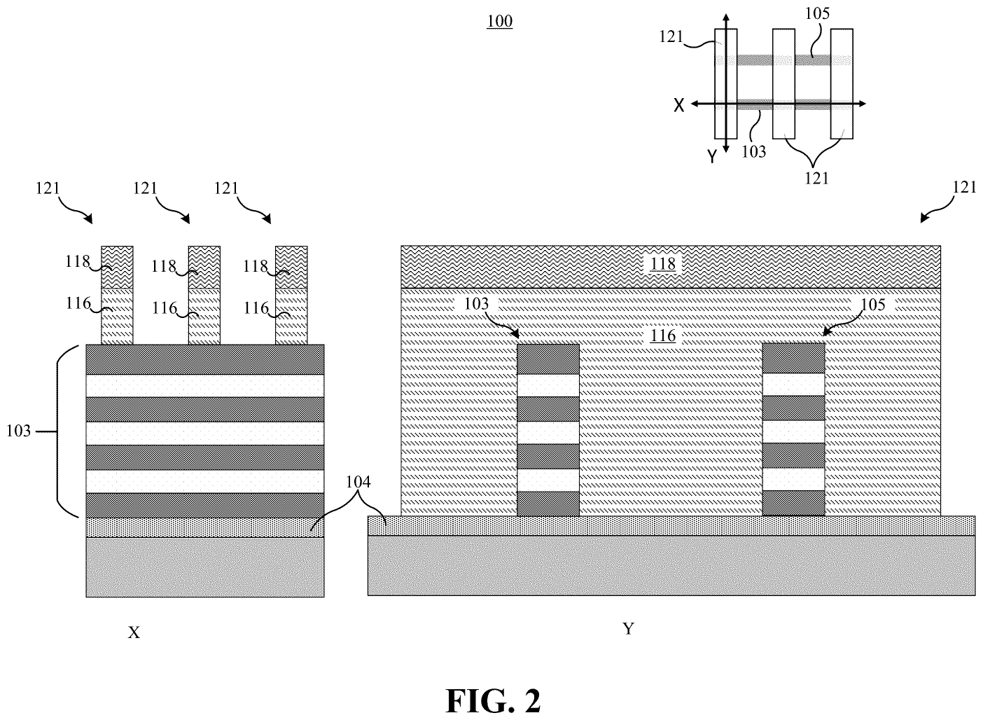

As shown in FIG. 1, after initial fabrication processing, semiconductor IC device 100 may include a substrate 102, an insulator layer 104, a nanosheet stack 103 that includes active semiconductor layers 108 and sacrificial layers 106, and a nanosheet stack 105 that includes active semiconductor layers 108 and sacrificial layers 106. The top-down view of FIG. 1 also shows a sacrificial gate structure 121, which is further depicted in FIG. 2.

The insulator layer 104 may be formed on the substrate 102. Thus, in various examples, substrate 102 is provided, insulator layer 104 is deposited over substrate 102, and then the nanosheet stacks 103, 105 are formed over the insulator layer 104. Alternatively, the initial substrate may be an insulator on substrate, such as a SiGeOI (SiGe on insulator substrate), a SOI (silicon on insulator substrate, or the like).

The nanosheet stacks 103, 105 may be formed by initially forming alternating blanket sacrificial layers and blanket active semiconductor layers. In certain examples, the first one of the blanket sacrificial layers is initially formed directly on an upper surface of the insulator layer 104. In other examples, certain layers may be formed between the upper surface of the insulator layer 104 and the first one of the blanket sacrificial layers. In an example, each blanket sacrificial layer is composed of silicon-germanium (e.g., SiGe, where the Ge ranges from about 25-40%). Next, a blanket active semiconductor layer is formed on an upper surface of the first one of the blanket sacrificial layers. In an example, the blanket active semiconductor layer is composed of silicon. Several additional blanket layers of the sacrificial layer and blanket active semiconductor layer are alternately formed. In the example illustrated, there are a total of three blanket sacrificial layers and three blanket active semiconductor layers that are alternately patterned to form the nanosheet stack 103. However, it should be appreciated that any suitable number of alternating layers may be formed. Although it is specifically contemplated that the blanket sacrificial layers can be formed from SiGe and that the blanket active semiconductor layers can be formed from Si, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials can be deposited by any appropriate mechanism. The first and second semiconductor materials (i.e., of the blanket sacrificial layers and the blanket active semiconductor layers) can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In certain embodiments, the blanket sacrificial layers have a vertical thickness ranging, for example, from approximately 3 nm to approximately 20 nm. In certain embodiments, the blanket active semiconductor layers have a vertical thickness ranging, for example, from approximately 3 nm to approximately 10 nm. Although seven total sacrificial layers and active semiconductor layers are depicted in semiconductor IC device 100, it should be appreciated that the nanosheet stack 103 can include any suitable number of layers. Although the range of 3-20 nm is cited as an example range of thickness, other thicknesses of these layers may be used. In certain examples, certain of the blanket sacrificial layers or the blanket active semiconductor layers may have different thicknesses relative to one another. Therefore, multiple epitaxial growth processes can be performed to form the alternating blanket sacrificial layers and the blanket active semiconductor layers.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP should be of a sufficient value to accommodate the replacement gate structure conductor(s) (e.g., work function metal) that will be formed in the spaces created by later removal of respective portions of the sacrificial layers 106 formed from the blanket sacrificial layers.

In some implementations, a mask layer (not shown) is formed on the uppermost nanosheet blanket layer. The mask layer may be comprised of any suitable material(s) known to one of skill in the art. The mask layer is patterned and used to perform the nanosheet patterning process. In the nanosheet patterning process, any suitable material removal process (e.g., reactive ion etching or RIE) may be used to remove portions of the various blanket layers down to the level of the insulator layer 104. Following the patterning process to the various blanket layers, nanosheet stacks 103, 105 are formed. As depicted, within each nanosheet stack 103, 105 there are alternating sacrificial layers 106 and active semiconductor layers 108 formed from the associated blanket layers, respectively. Subsequently, the mask layer may be removed.

Referring now to FIG. 2, this figure depicts cross-sectional views of the semiconductor IC device 100 after additional fabrication operations where sacrificial gate structure 121 is formed. Sacrificial gate structure 121 may include a sacrificial gate 116 formed upon a sacrificial gate oxide layer (not shown) and a gate hard mask 118 formed upon the sacrificial gate 116.

The sacrificial gate 116 may be formed on the sacrificial gate oxide layer by any suitable deposition and/or patterning processes known to one of skill in the art. In one example, the sacrificial gate 116 is formed by depositing a thin sacrificial gate oxide (e.g., SiO₂, or the like) layer (not shown), followed by depositing a layer of amorphous silicon (a-Si) as the sacrificial gate 116. The sacrificial gate 116 may be composed of polycrystalline silicon (poly silicon), amorphous silicon, and/or an oxide, such as, SiO₂. A gate hard mask 118 is also formed on a topside of the sacrificial gate 116. The gate hard mask 118 is formed for subsequent sacrificial gate and nanosheet patterning. The gate hard mask 118 can be composed of various nitride materials including, but not limited to, a nitride, an oxide, silicon nitride (SiN), and/or a combination of a nitride material and an oxide material. As depicted in the Y cross-section, the sacrificial gate 116 wraps around the nanosheet stacks 103, 105. As described below, subsequent removal of the sacrificial gate 116 allows an access point for later removal of the sacrificial layers 106. In certain examples, gate patterning may be performed by first patterning the gate hard mask 118 and then using the patterned gate hard mask 118 to etch the sacrificial gates 116.

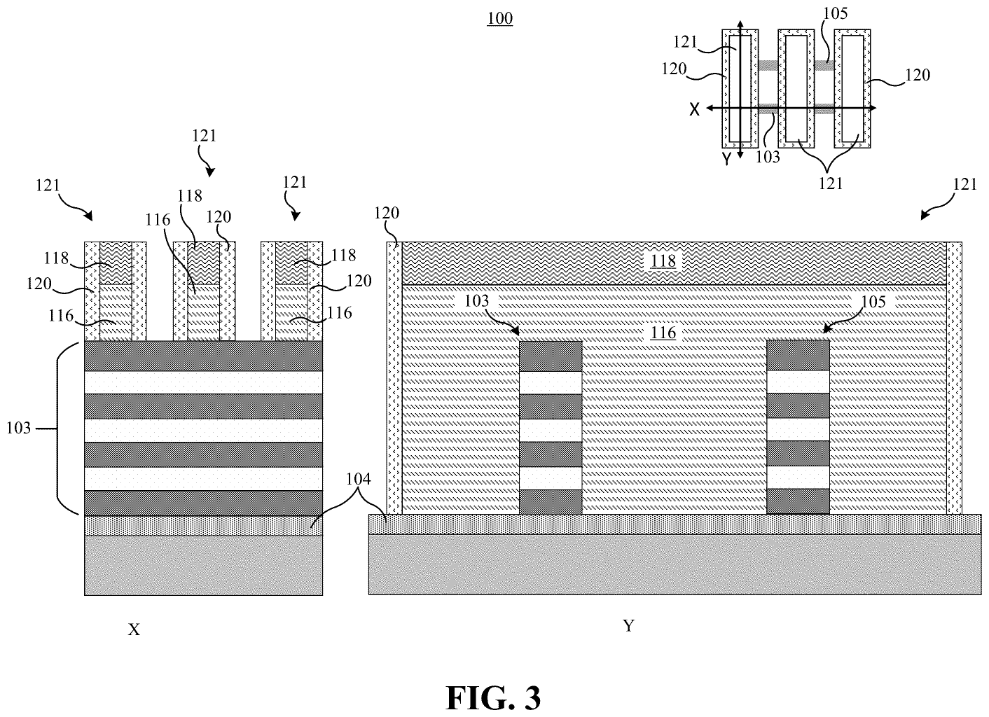

Referring now to FIG. 3, this figure depicts a cross-sectional view of the semiconductor IC device 100 after additional fabrication operations where spacer 120 is formed upon sidewalls of the sacrificial gate structure 121. The spacer 120 can be deposited by any suitable techniques, such as ALD, CVD, PVD, thermal oxidation, combinations thereof, or other suitable techniques. The spacer 120 material may be composed of a dielectric material, such as silicon nitride, SiBCN, SiNC, SIN, SiCO, SiNOC, or a combination thereof, or the like, and can include a single material layer or different material layers. In addition to being formed upon the sidewalls of the sacrificial gate structure 121, spacer 120 may also be formed upon the insulator layer 104 and around the nanosheet stacks 103, 105.

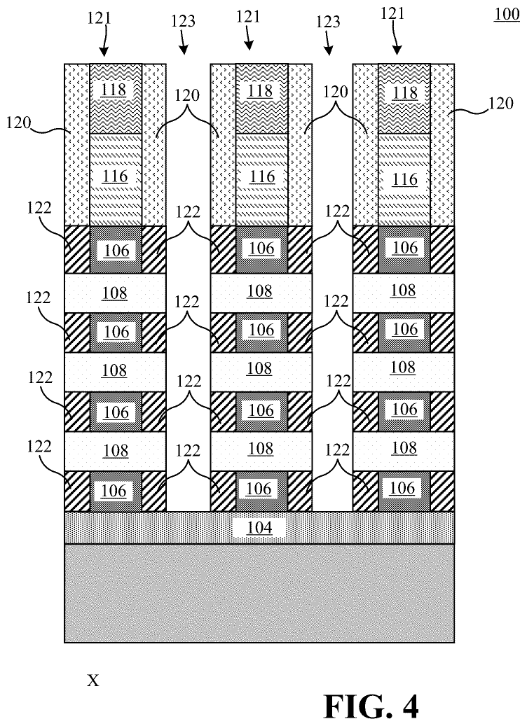

Referring now to FIG. 4, this figure depicts cross-sectional views of the semiconductor IC device 100 after additional fabrication operations where nanosheet stacks 103, 105 are patterned by removing portions thereof that are not protected by sacrificial gate structure 121 and/or by spacer 120, where sacrificial layers 106 are indented underneath the spacer 120, and where inner spacers 122 are formed in the indents.

Undesired portions of nanosheet stacks 103, 105 that are not protected by sacrificial gate structure 121 and/or by spacer 120 may be etched or otherwise removed. The etch may utilize the top surface of insulator layer 104 as an etch stop. The retained one or more portions of nanosheet stacks 103, 105 may be such portions thereof that were protected generally below the sacrificial gate structure 121 and/or by spacer 120.

Subsequently, the semiconductor IC device 100 is subjected to a directional reactive ion etch (RIE) process, which can remove portions of the sacrificial layers 106 not covered by the sacrificial gate 116 (and the sacrificial gate hard mask 118). The RIE can use a boron-based chemistry, a fluorine-based chemistry, or a chlorine-based chemistry, for example, which selectively recesses the exposed portions sacrificial layers 106 (e.g., those portions of sacrificial layers 106 generally below spacer 120, etc.) without significantly removing the active semiconductor layers 108.

Subsequently, inner spacers 122 are deposited in the recesses that were previously formed into the sacrificial layers 106. In certain embodiments, after the formation of the inner spacers 122, an isotropic etch process is performed to create outer vertical edges to the inner spacers 122 that align with outer vertical edges of the active semiconductor layers 108. In certain embodiments, the material of the inner spacer 122 is a dielectric material such as SIN, SiO, SiBCN, SiOCN, SiCO, etc.

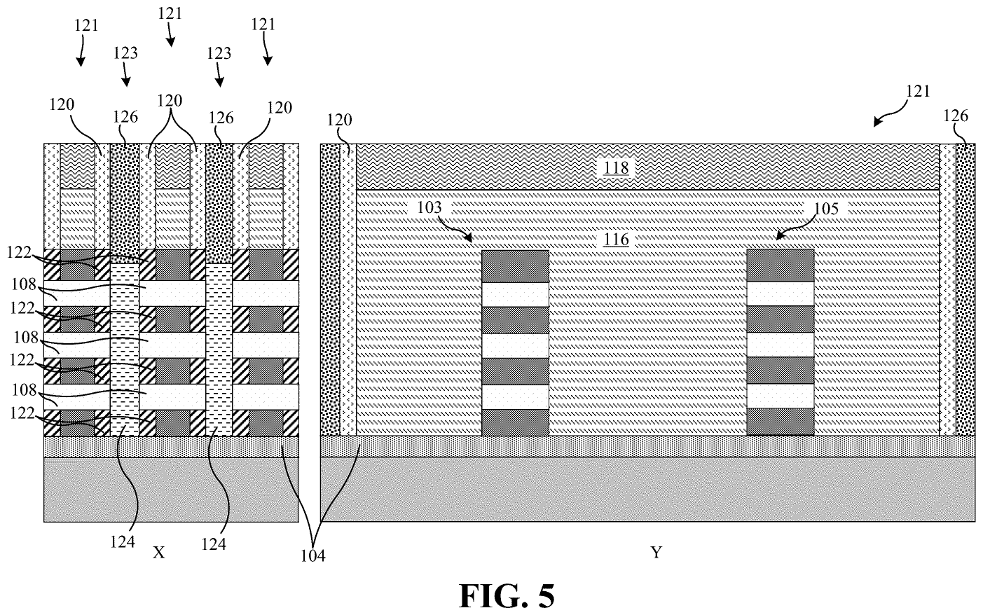

Referring now to FIG. 5, this figure depicts cross-sectional views of the semiconductor IC device 100 after additional fabrication operations where source/drain (S/D) region 124 is formed over the sidewalls of and/or in between one or more nanosheet stacks, as depicted in the X cross-section, and over the insulator layer 104 and after additional fabrication operations where interlayer dielectric (ILD) 126 is formed over the insulting layer 104 and over S/D region 124 and upon spacer 120.

The S/D region 124 forms either a source or a drain, respectively, to each neighboring nanosheet FET. S/D regions 124 may be epitaxially grown or formed. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

The S/D region 124 may be formed by epitaxially growing a source/drain epitaxial region within the recess or opening between neighboring nanosheet FETs. In some examples, S/D region 124 is formed by in-situ doped epitaxial growth. In some embodiments, the S/D region 124 epitaxial growth may overgrow above the upper surface of the semiconductor IC device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors. The doping concentration in the S/D region 124 can be in the range of 1×10¹⁹ cm⁻³ to 2×10²¹ cm⁻³, or preferably between 2×10²⁰ cm⁻³ to 7×10²⁰ cm⁻³.

In certain implementations, the S/D region 124 may be partially recessed such that an upper portion of the S/D region 124 are removed. For example, the upper portion of the one or more S/D regions 124 may be etched or otherwise removed. The etch may be timed or otherwise controlled to stop the removal of S/D region 124 such that the top surface of S/D region 124 is above the upper surface of the topmost active semiconductor layer 108.

Subsequently, the ILD 126 may be formed around the S/D region 124, upon insulator layer 104, and upon spacer 120. The ILD 126 may be formed by depositing a dielectric material upon S/D region 124, upon insulator layer 104, and upon spacer 120. The ILD 126 can be any suitable material, such as, for example, porous silicates, carbon doped oxides, silicon dioxides, silicon nitrides, silicon oxynitrides, or other dielectric materials. Any known manner of forming the ILD 126 can be utilized. The ILD 126 can be formed using, for example, CVD, PECVD, ALD, flowable CVD, spin-on dielectrics, or PVD.

In an example, the ILD 126 may be formed to a thickness above the top surface of the semiconductor IC device 100 and subsequently etched back such that the top surface of the ILD 126 is coplanar with a top surface of the gate hard mask 118 and/or a top surface of spacer(s) 120. In another example, a planarization process, such as a chemical mechanical polish (CMP), may be performed to create a planar upper surface for the semiconductor IC device 100.

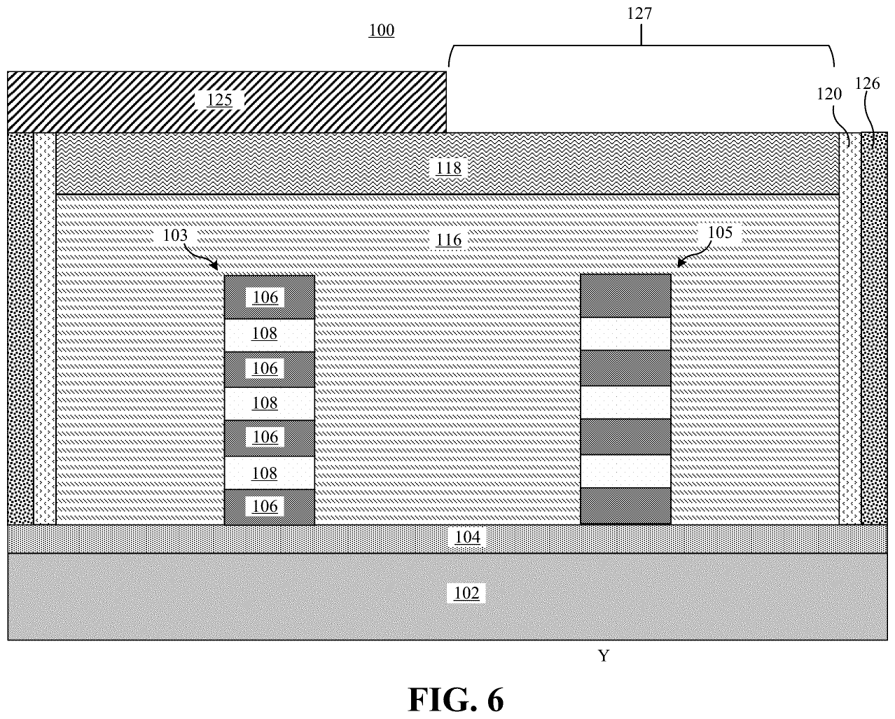

Referring now to FIG. 6, this figure depicts a cross-sectional view of the semiconductor IC device 100 after additional fabrication operations where a channel cell 127 is defined. Channel cell 127 may be defined by forming a mask layer 125 generally above nanosheet stack 103 that protects the sacrificial gate structure 121 materials therearound. The mask layer 125 may be formed by depositing a mask layer comprised of any suitable material(s) known to one of skill in the art. The mask layer 125 is patterned by lithography and etching techniques to remove a portion of the mask layer 125 that is generally above the sacrificial gate structure 121 around nanosheet stack 105. A patterned end surface of the mask layer 125 may be generally between the nanosheet stacks 103, 105. For example, as depicted, a patterned vertical end surface of the mask layer 125 may be equidistant to the nanosheet stacks 103, 105. The patterning of mask layer 125 at least partially defines channel cell 127 within a portion of a gate (the sacrificial gate structure 121 at the present stage of fabrication) location. The boundary of channel cell 127 may be formed by the spacer 120, the mask layer 125, and the insulator layer 104.

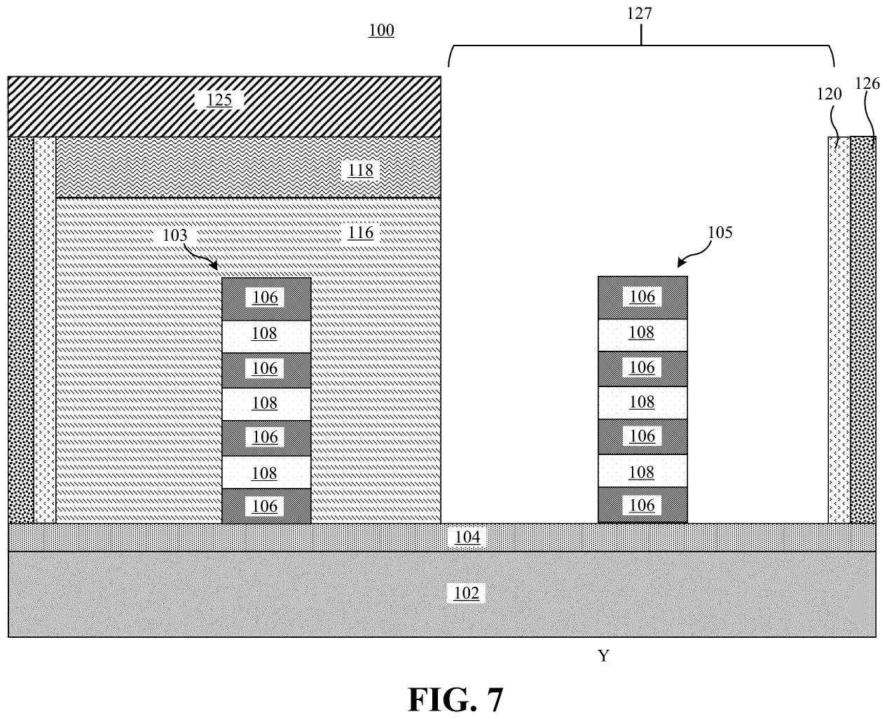

Referring now to FIG. 7, this figure depicts a cross-sectional view of the semiconductor IC device 100 after additional fabrication operations where a portion of the sacrificial gate structure 121 within channel cell 127 is removed and nanosheet stack 105 is exposed.

The portion of sacrificial gate structure 121 within channel cell 127 may be removed by removing associated portions of gate hard mask 118, sacrificial gate 116 and sacrificial gate oxide by a removal technique, such as one or more series of etches. For example, such removal may be accomplished by an etching process which may include a dry etching process such as RIE, plasma etching, ion etching or laser ablation. The etching can further include a wet chemical etching process in which one or more chemical etchants are used to remove the associated portions of hard mask 118, sacrificial gate 116, and/or sacrificial gate oxide within channel cell 127. Subsequently, mask layer 125 may be removed.

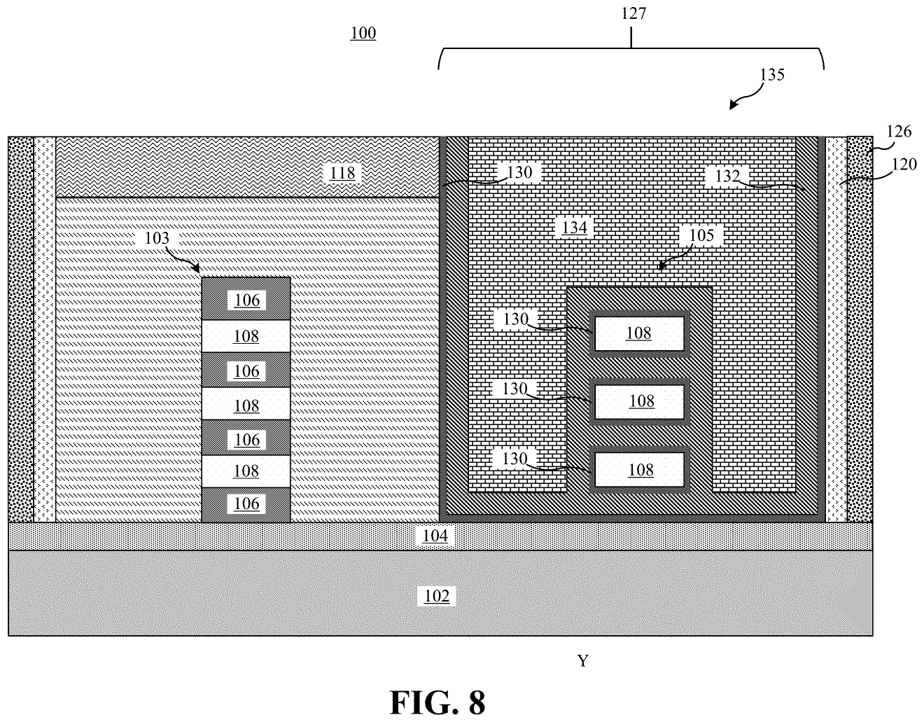

Referring now to FIG. 8, this figure depicts a cross-sectional view of the semiconductor IC device 100 after additional fabrication operations where sacrificial layers 106 are removed and a replacement gate structure 135 is formed within channel cell 127 around the active semiconductor layers 108.

After the removal of sacrificial layers 106, void spaces between the active semiconductor layers 108 are formed. It should be appreciated that during the removal of the sacrificial gate 116, the sacrificial oxide layer, the sacrificial layers 106, and/or the like, appropriate etchants are used that do not significantly remove material of active semiconductor layers 108, insulator layer 104, inner spacers 122, etc. The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF4), nitrogen trifluoride (NF3), sulfur hexafluoride (SF6), and helium (He), and Chlorine trifluoride (CIF3). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF4), and gas mixture with hydrogen (H2). Chemical vapor etching can be performed by CVD with suitable pressure and temperature.

Replacement gate structure 135 may be formed by initially forming an interfacial layer (not shown) on the interior surfaces of the spacer 120 and the interior surfaces of the active semiconductor layers 108, the inner spacers 122, the gate hard mask 118, the sacrificial gate 116, and the insulator layer 104, etc. Then, a high-K layer 130 is formed to cover the surfaces of exposed surfaces of the interfacial layer. The high-K layer 130 can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-K layer 130 can include a single layer or multiple layers, such as metal layer, liner layer, wetting layer, and adhesion layer. In other embodiments, the high-K layer 130 can include, e.g., Ti, Ag, Al, TiAIN, TaC, TaCN, TaSiN, Mn, Zr, TiN, TaN, Ru, Mo, Al, WN, Cu, W, or any suitable materials.

Replacement gate structure 135 may be further formed by depositing a work function (WF) gate 132 upon the high-K layer 130. The WF gate 132 can be comprised of metals, such as, e.g., copper (Cu), cobalt (Co), aluminum (Al), platinum (Pt), gold (Au), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the work function metal (WFM) gate 132 sets the threshold voltage (Vt) of the transistor associated with channel cell 127. The high-K layer 130 separates the WF gate 132 from the nanosheet channel(s) (i.e., active semiconductor layers 108). The WF gate 132 may be formed to a thickness to generally fill the gaps between active semiconductor layers 108.

Replacement gate structure 135 may be further formed by depositing a conductive fill gate 134 upon the WF gate 132. The conductive fill gate 134 can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. Subsequent to the replacement gate structure 135 formation, the top surface of the semiconductor IC device 100 may be planarized by a planarization technique such as a CMP.

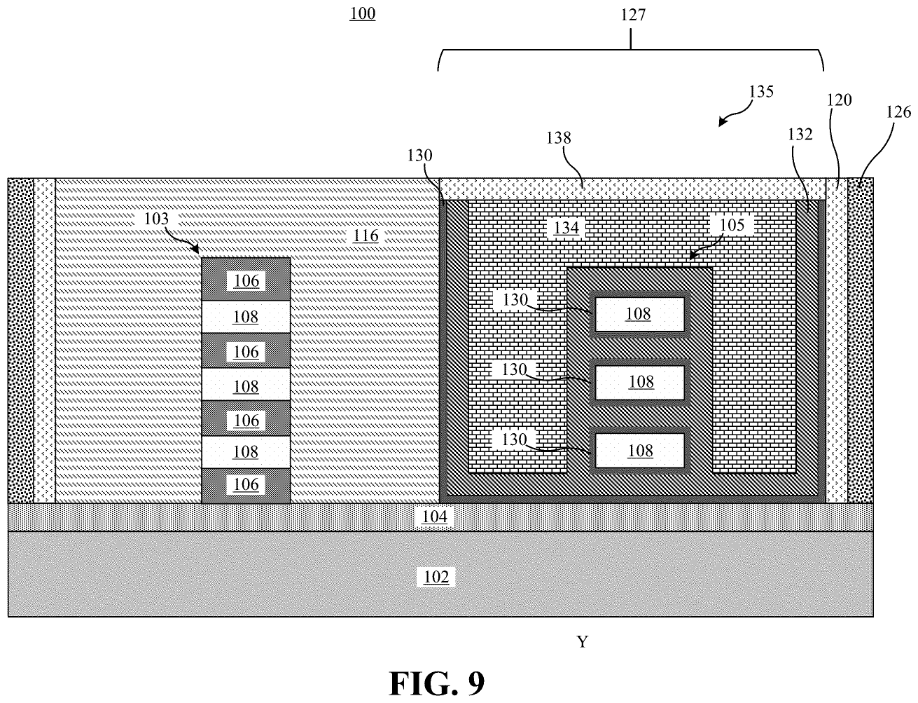

Referring now to FIG. 9, this figure depicts cross-sectional views of the semiconductor IC device 100 after additional fabrication operations where the replacement gate structure 135 is recessed and a sacrificial gate cap 138 is formed. The replacement gate structure 135 may be recessed by etching techniques. After the removal of replacement gate structure 135, a void above the replacement gate structure 135 between the spacer 120 and sacrificial gate 116 are formed. The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF4), nitrogen trifluoride (NF3), sulfur hexafluoride (SF6), and helium (He), and Chlorine trifluoride (CIF3). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF4), and gas mixture with hydrogen (H2). Chemical vapor etching can be performed by CVD with suitable pressure and temperature.

Subsequently, the sacrificial gate cap 138 may be formed within the void. The sacrificial gate cap 138 can be deposited by any suitable techniques, such as ALD, CVD, PVD, thermal oxidation, combinations thereof, or other suitable techniques followed by a CMP to expose sacrificial gate 116 containing or otherwise associated with nanosheet stack 103. The sacrificial gate cap 138 material may be dielectric material, such as silicon nitride, SiBCN, SiNC, SIN, SiCO, SiNOC, or a combination thereof, or the like, and can include a single material layer or different material layers.

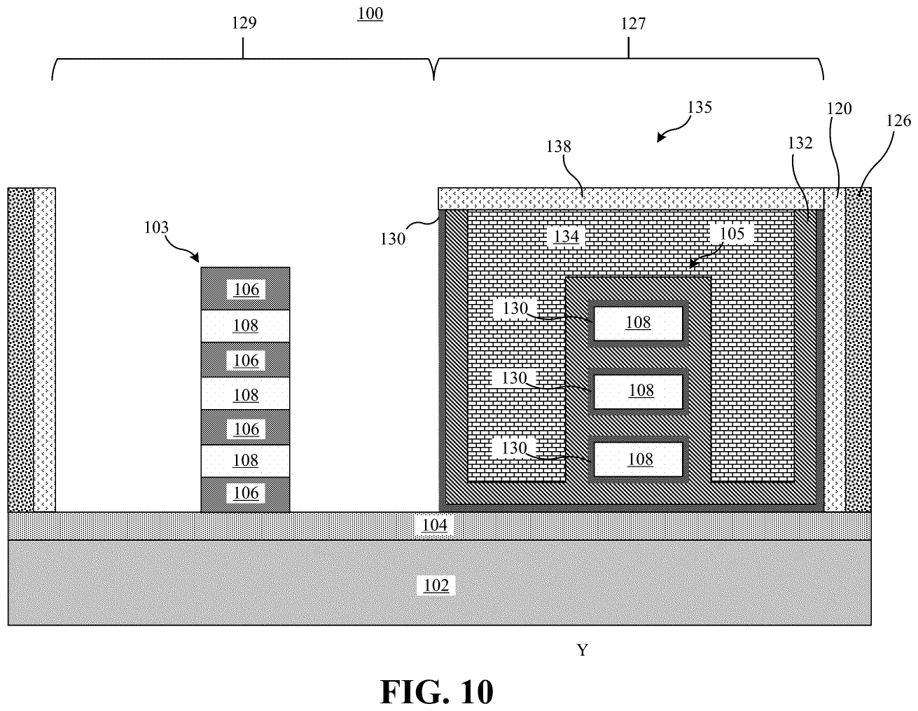

Referring now to FIG. 10, this figure depicts cross-sectional views of the semiconductor IC device 100 after additional fabrication operations where a channel cell 129 is defined and where a portion of the sacrificial gate structure 121 within channel cell 129 is removed and nanosheet stack 103 is exposed. The boundary of channel cell 129 may be formed by the spacer 120, the channel cell 127 (e.g., sacrificial gate cap 138, the interfacial layer associated with high-K layer 130, the WF metal 132, the gate conductor fill 134, and the insulator layer 104.

The portion of sacrificial gate structure 121 within channel cell 129 may be removed by removing associated portions sacrificial gate 116 and sacrificial gate oxide by a removal technique, such as one or more series of etches. For example, such removal may be accomplished by an etching process which may include a dry etching process such as RIE, plasma etching, ion etching or laser ablation. The etching can further include a wet chemical etching process in which one or more chemical etchants are used to remove the associated portions sacrificial gate 116 and/or sacrificial gate oxide within channel cell 129.

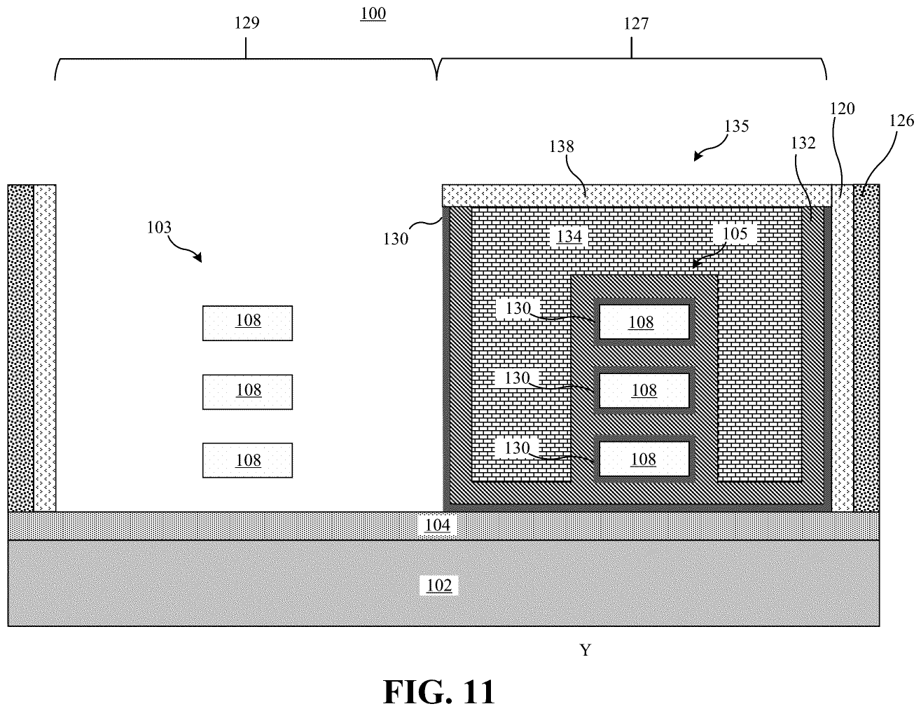

Referring now to FIG. 11, this figure depicts cross-sectional views of the semiconductor IC device 100 after additional fabrication operations where sacrificial layers 106 are removed from nanosheet stack 103.

After the removal of sacrificial layers 106, void spaces between the active semiconductor layers 108 within nanosheet stack 103 are formed. It should be appreciated that during the removal of the sacrificial gate 116, the sacrificial oxide layer, and/or the sacrificial layers 106, etc. appropriate etchants are used may not significantly remove material of active semiconductor layers 108, insulator layer 104, inner spacers 122, the interfacial layer associated with high-K layer 130 (if present), high-K layer 130, sacrificial gate cap 138, or the like. In some examples, the interfacial layer associated with high-K layer 130 and the high-layer 130 may also be removed along with the sacrificial layers 106.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF4), nitrogen trifluoride (NF3), sulfur hexafluoride (SF6), and helium (He), and Chlorine trifluoride (CIF3). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF4), and gas mixture with hydrogen (H2). Chemical vapor etching can be performed by CVD with suitable pressure and temperature.

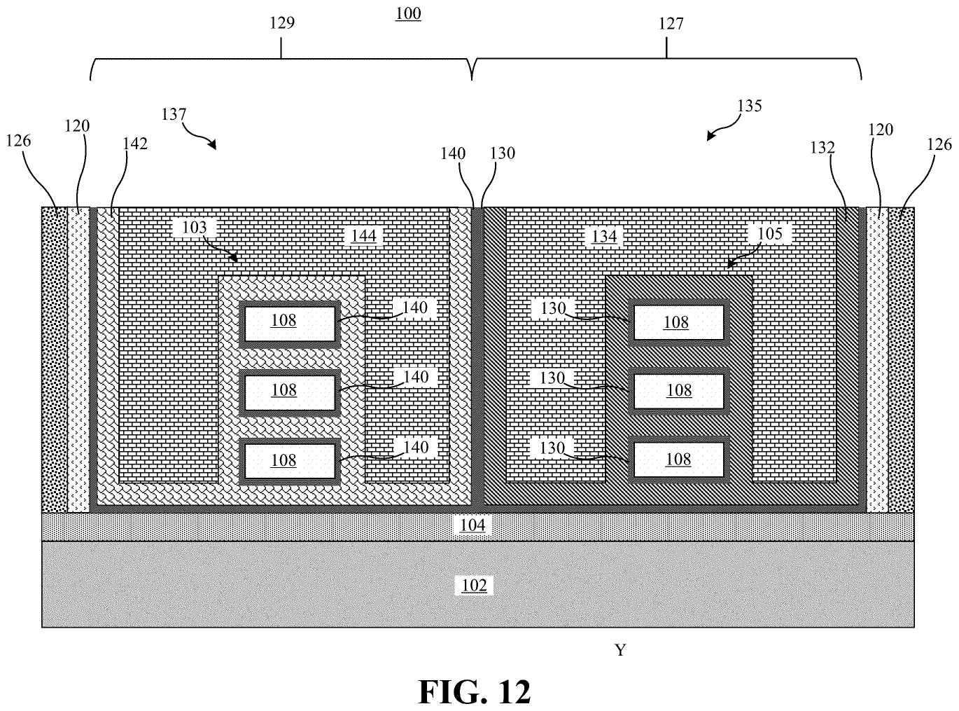

Referring now to FIG. 12, this figure depicts cross-sectional views of the semiconductor IC device 100 after additional fabrication operations where a replacement gate structure 137 is formed within channel cell 129 around the active semiconductor layers 108 of nanostructure stack 103.

Replacement gate structure 137 may be formed by initially forming an interfacial layer (not shown) on the interior surfaces of the spacer 120 and the interior surfaces of the active semiconductor layers 108, the inner spacers 122, the interfacial layer associated with high-k layer 130 (if present) or the high-layer 130 if the interfacial layer is not present, and the insulator layer 104, etc. Then, a high-K layer 140 is formed to cover the surfaces of exposed surfaces of the interfacial layer. The high-K layer 140 can be deposited by any suitable techniques, such as ALD, CVD, metal-organic CVD (MOCVD), physical vapor deposition (PVD), thermal oxidation, combinations thereof, or other suitable techniques. The high-K layer 140 can include a single layer or multiple layers, such as metal layer, liner layer, wetting layer, and adhesion layer. In other embodiments, the high-K layer 140 can include, e.g., Ti, Ag, Al, TiAIN, TaC, TaCN, TaSiN, Mn, Zr, TiN, TaN, Ru, Mo, Al, WN, Cu, W, or any suitable materials.

Replacement gate structure 137 may be further formed by depositing a work function (WF) gate 142 upon the high-K layer 140. The WF gate 142 can be comprised of metals, such as, e.g., copper (Cu), cobalt (Co), aluminum (Al), platinum (Pt), gold (Au), titanium (Ti), nitride (N) or any combination thereof. Generally, the material of WF gate 142 may be different than the material of MFM gate 132. Whereas the material of MFM gate 132 may be chosen to improve or set the threshold voltage (Vt) of the transistor associated with channel cell 127 the material of MFM gate 142 may be chosen to improve or set the threshold voltage (Vt) of the transistor associated with channel cell 129. When the transistor associated with channel cell 127 is a different type (p-type) relative to the transistor associated with channel cell 129 (n-type) the relative materials of WF gate 132 and WF gate 142 are typically different. In a particular implementation, the WF gate 142 is comprised of a nFET WF metal and the WF gate 132 is comprised of a pFET WF metal, or vice versa.

The WF gate 142 material can be deposited by a suitable deposition process, for example, chemical vapor deposition (CVD), plasma enhanced chemical vapor deposition (PECVD), physical vapor deposition (PVD), plating, thermal or e-beam evaporation, or sputtering. As indicated above, the WF gate 142 sets the threshold voltage (Vt) of the transistor associated with channel cell 129. The high-K layer 140 separates the WF gate 142 from the nanosheet channel(s) (i.e., active semiconductor layers 108 of nanosheet stack 103). The WF gate 142 may be formed to a thickness to generally fill the gaps between active semiconductor layers 108 of nanosheet stack 103.

Replacement gate structure 135 may be further formed by depositing a conductive fill gate 144 upon the WF gate 142. The conductive fill gate 144 can be comprised of metals such as tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. Subsequent to the replacement gate structure 137 formation, the top surface of the semiconductor IC device 100 may be planarized by a planarization technique such as a CMP. As such, in some implementations, the top surface of replacement gate structure 135 may be coplanar with the top surface of the replacement gate structure 137. As replacement gate structure 135 and replacement gate structure 137 were fabricated in association with the same sacrificial gate structure 121, replacement gate structure 135 and replacement gate structure 137 may be referred herein as a generic, single, or same replacement gate structure, or simply as the replacement gate structure.

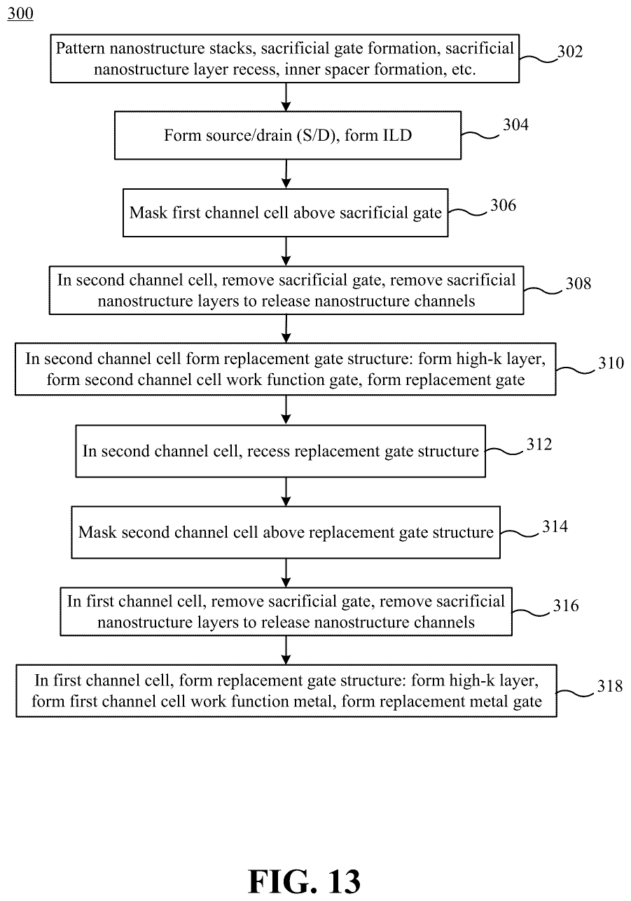

FIG. 13 depicts a method 300 of fabricating semiconductor IC device 100 that includes relatively different work function materials (i.e., WF gate 132 and WF gate 142) within the replacement gate structure, according to embodiments. Method 300 begins at block 302 with forming nanosheet layers and patterning nanosheet stacks 103, 105 therefrom, with forming sacrificial gate structure 121, with forming gate spacer 120, with indenting the sacrificial nanosheet layers 106 underneath the gate spacer 120, and with forming inner spacers 122 within the indents.

Method 300 may continue, at block 304, with forming S/D regions 124 over the sidewalls of and/or in between one or more nanosheet stacks and over the insulator layer 104 and with forming ILD 126 over the insulting layer 104 and over S/D region 124 and upon spacer 120.

Method 300 may continue, at block 306, with masking channel cell 129 with mask layer 125 while exposing channel cell 127 by patterning or opening mask layer 125. Method 300 may continue, at block 308, with removing the sacrificial gate structure within the channel cell 127 and with removing the sacrificial layers 106 to release the active semiconductor layers 108 within nanosheet stack 105.

Method 300 may continue, at block 310, with forming replacement gate structure 135 in place of the removed sacrificial gate structure within the channel cell 127. The replacement gate structure 135 includes WF gate 132 generally around active semiconductor layers 108 within nanosheet stack 105 to set the threshold voltage (Vt) of the transistor associated with channel cell 127. The replacement gate structure 135 may further include interfacial layer, high-K layer 130, and/or conductive fill gate 134.

Method 300 may continue, at block 312, with recessing the replacement gate structure within the channel cell 127 and, at block 314, with forming sacrificial gate cap 138 above the recessed replacement gate structure within the channel cell 127 and upon a sidewall of the sacrificial gate structure within channel cell 129.

Method 300 may continue, at block 316, with removing the sacrificial gate structure within the channel cell 129 and with removing the sacrificial layers 106 to release the active semiconductor layers 108 within nanosheet stack 103.

Method 300 may continue, at block 318, with forming replacement gate structure 137 in place of the removed sacrificial gate structure within the channel cell 129. The replacement gate structure 137 includes WF gate 142 generally around active semiconductor layers 108 within nanosheet stack 103 to set the threshold voltage (Vt) of the transistor associated with channel cell 129. The replacement gate structure 137 may further include interfacial layer, high-K layer 140, and/or conductive fill gate 144.

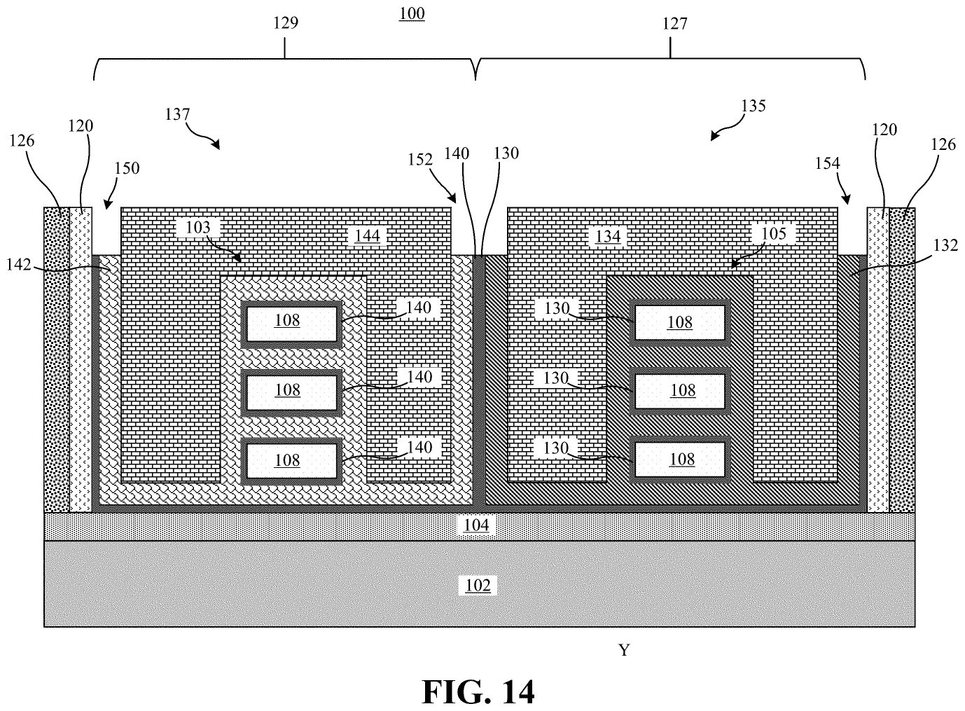

Referring now to FIG. 14, this figure is a cross-sectional view of semiconductor IC device 100 after additional fabrication operations, where high-K layer 130, WF gate 132, high-K layer 140, and WF gate 142 are partially recessed. The high-layer 130, WF gate 132, high-layer 140, and WF gate 142 may be partially recessed by etching techniques. For example, a selective etch may remove high-k layer 130, WF gate 132, high-K layer 140, and WF gate 142 without significantly removing the spacer 120, ILD 126, conductive fill gate 134, and conductive fill gate 144. As the high-k layer 130, WF gate 132, high-K layer 140, and WF gate 142 are partially recessed, the respective top surfaces thereof may be below the respective top surfaces of conductive fill gate 134 and conductive fill gate 144. In a particular implementation, as depicted, the respective recessed top surfaces of high-K layer 130, WF gate 132, high-K layer 140, and WF gate 142 may be above the respective top surfaces of the portions of WF gate 132 and WF gate 142 above the topmost active semiconductor layer 108 with nanosheet stack 103, 105, respectively. In alternative implementations, the high-K layer 130, WF gate 132, high-K layer 140, and WF gate 142 may be recessed to a relatively greater depth (e.g., respective recessed top surfaces of high-K layer 130, WF gate 132, high-K layer 140, and WF gate 142 may be between active semiconductor layers 108, or the like). Generally, the high-K layer 130, WF gate 132, high-K layer 140, and WF gate 142 may be recessed to a depth to retain generally vertical portions thereof between conductive fill gate 134 and conductive fill gate 144. The respective top surfaces of the recessed high-K layer 130, WF gate 132, high-layer 140, and WF gate 142 may or may not be coplanar.

The recessing of high-K layer 130, WF gate 132, high-K layer 140, and WF gate 142 forms at least opening 152 that is bounded by conductive fill gate 144, conductive fill gate 134, and spacer 120 and may optionally form opening 150 that is bounded by the conductive fill gate 144 and spacer 120, may optionally form opening 154 that is bounded by the conductive fill gate 134 and spacer 120.

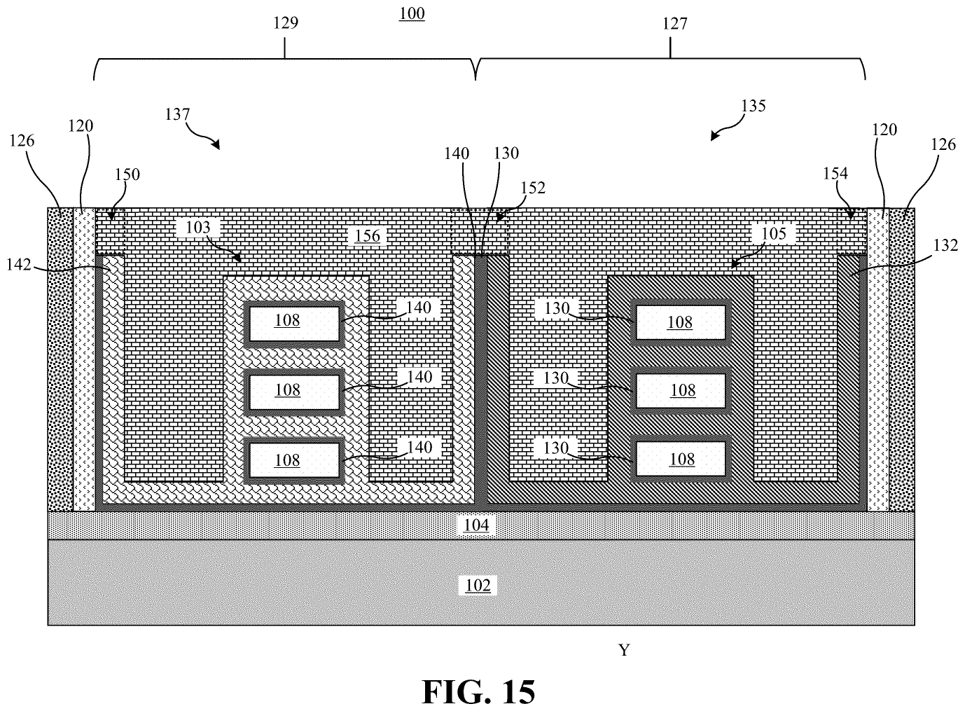

Referring now to FIG. 15, this figure is a cross-sectional view of semiconductor IC device 100 after additional fabrication operations, where a common conductive gate 156 is formed from conductive fill gate 134 and from conductive fill gate 144 by depositing a conductive material (e.g., metal, or the like) within at least opening 152 and optionally within openings 150, 154 (if present).

Common conductive gate 156 may be formed by melding together or generally connecting conductive fill gate 134 and conductive fill gate 144 by the deposition of conductive material within opening 152. The conductive material can be comprised of metals such as tungsten, aluminum, ruthenium, rhodium, cobalt, copper, tantalum, titanium, carbon nanowire materials including graphene, or the like. The material can be deposited by a suitable deposition process, for example, chemical vapor deposition (CVD), plasma enhanced chemical vapor deposition (PECVD), physical vapor deposition (PVD), plating, thermal or e-beam evaporation, or sputtering. Subsequent to the deposition of conductive material within openings 150, 152, and/or 154, the top surface of the semiconductor IC device 100 may be planarized by a planarization technique such as a CMP.

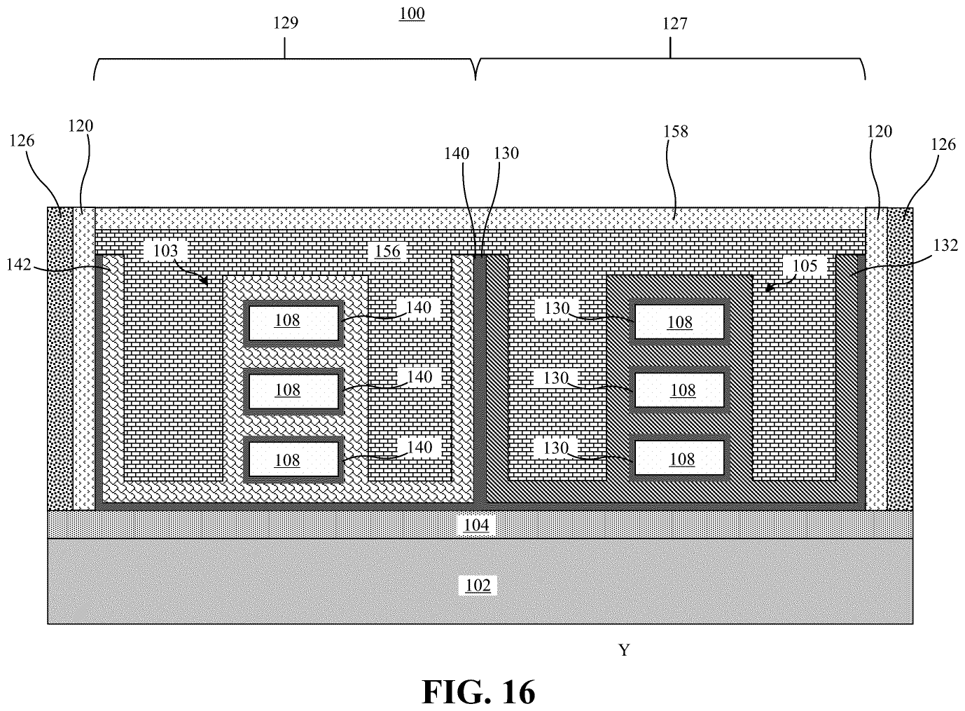

Referring now to FIG. 16, this figure depicts cross-sectional views of the semiconductor IC device 100 after additional fabrication operations where the common conductive gate 156 is recessed and a replacement gate cap 158 is formed. The common conductive gate 156 may be recessed by etching techniques. After the recessing of common conductive gate 156, a void above the common conductive gate 156 between the spacer 120 is formed. The dry and wet etching processes can have etching parameters that can be tuned, such as etchants used, etching temperature, etching solution concentration, etching pressure, source power, RF bias voltage, RF bias power, etchant flow rate, exposure time, and other suitable parameters so as to achieve the predetermined depth of partial removal of common conductive gate 156. In a particular implementation, as depicted, common conductive gate 156 is recessed to a depth so as to retain at least some of the conductive material formed within opening 152 so as to maintain the melding together or generally connecting of the conductive fill gate 134 and conductive fill gate 144. In other words, common conductive gate 156 may not be recessed to a depth that would effectively separate the common conductive gate 156 back into conductive fill gate 134 and conductive fill gate 144.

Subsequently, the replacement gate cap 158 may be formed within the void. The replacement gate cap 158 can be deposited by any suitable techniques, such as ALD, CVD, PVD, thermal oxidation, combinations thereof, or other suitable techniques. The replacement gate cap 158 material may be dielectric material, such as silicon nitride, SiBCN, SiNC, SIN, SiCO, SiNOC, or a combination thereof, or the like, and can include a single material layer or different material layers. After the formation of replacement gate cap 158, the top surface of the semiconductor IC device 100 may be planarized by a planarization technique such as a CMP.

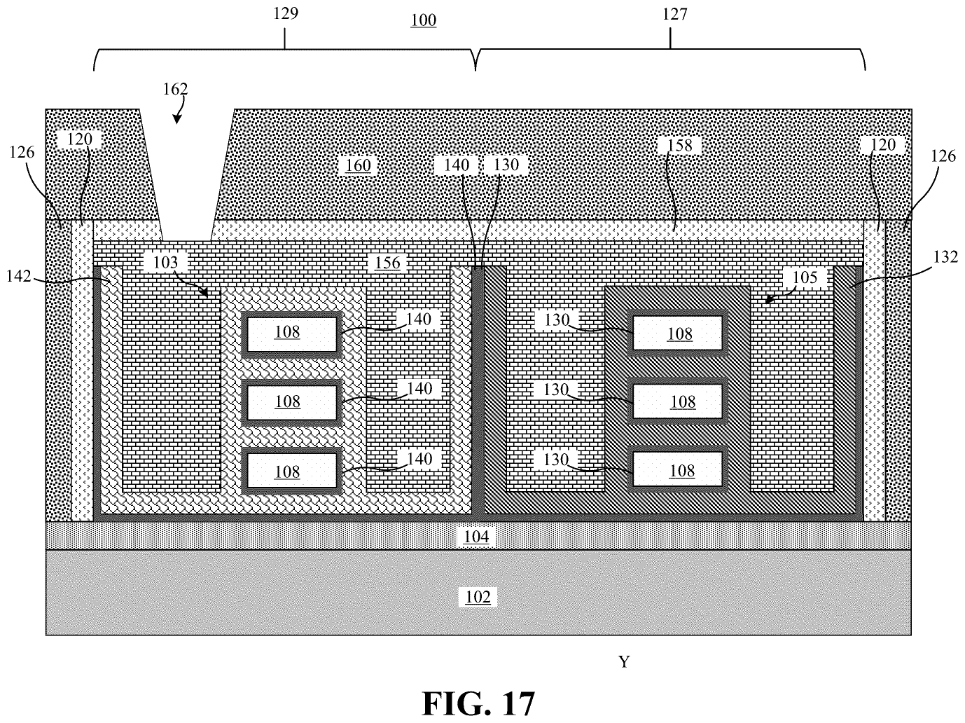

Referring now to FIG. 17, this figure is a cross-sectional view of semiconductor IC device 100 after additional fabrication operations, where ILD 160 is formed and gate contact opening 162 is formed.

The ILD 160 may be formed upon the top surface of ILD 126, spacer 120, replacement gate cap 158, or the like. The ILD 160 may be formed by depositing a dielectric material, such as, for example, porous silicates, carbon doped oxides, silicon dioxides, silicon nitrides, silicon oxynitrides, or other dielectric materials. Any known manner of forming the ILD 160 can be utilized. The ILD 160 can be formed using, for example, CVD, PECVD, ALD, flowable CVD, spin-on dielectrics, or PVD.

Subsequently, gate contact opening 162 is formed within ILD 160. The formation of gate contact opening 162 may include etching the ILD 160 to form the opening. The opening may expose the common conductive gate 156, may be located within channel cell 127, may be located within channel cell 129, or may located at the interface or boundary of channel cell 127 and channel cell 129. In particular examples, the gate contact opening 162 may be located vertically above the active semiconductor layers 108 of nanosheet stack 103 within channel cell 129, the gate contact opening 162 may be located vertically above the active semiconductor layers 108 of nanosheet stack 105 within channel cell 127, the gate contact opening 162 may be located vertically above both the WF gate 132 and the WF gate 142 at the interface or boundary of channel cell 127 and channel cell 129.

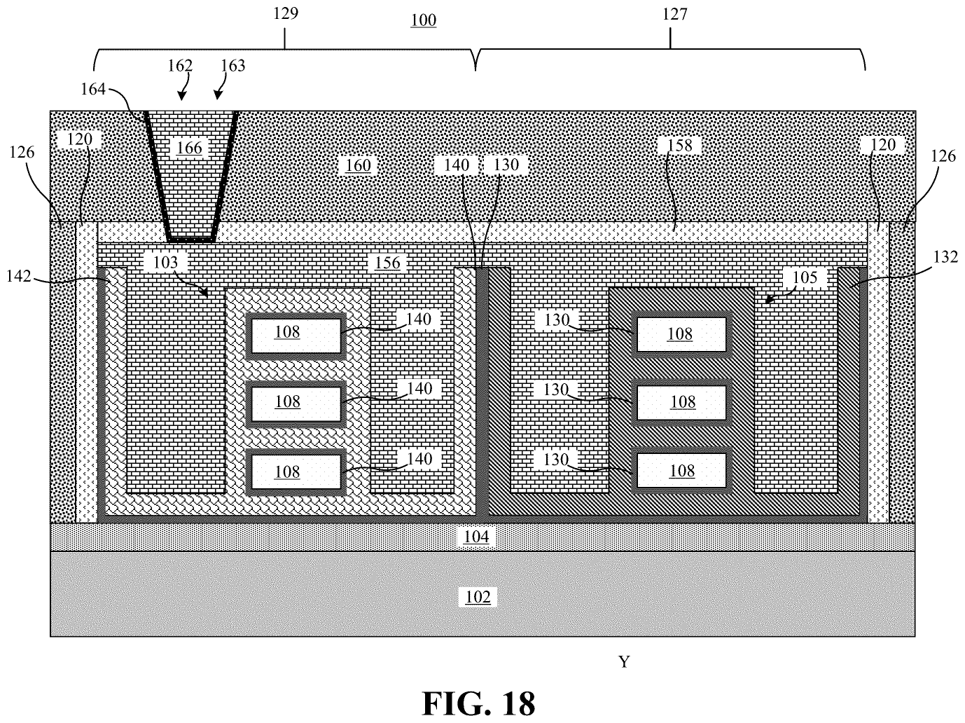

Referring now to FIG. 18, this figure is a cross-sectional view of semiconductor IC device 100 after additional fabrication operations, a gate contact 163 is formed in gate contact opening 162. The formation of the gate contact 163 may include etching the ILD 160 to form the gate contact opening 162 therein, forming a blanket conductive barrier layer extending into the gate contact opening 162, depositing a metal or conductive material over the blanket conductive barrier layer, and performing a planarization process, such as a CMP process or a mechanical grinding process, to remove excess portions of the conductive barrier layer and the conductive material. Gate contact 163 may consist of a liner 164 formed of Ni, NiPt, Ti, TiN, TaN, etc. and a conductive fill 166 deposited thereupon, such as Al, Ru, W, Co, Cu, etc.

The gate contact 163 may contact or otherwise meld to the exposed portion of the common conductive gate 156, may be located within channel cell 127, may be located within channel cell 129, or may located at the interface or boundary of channel cell 127 and channel cell 129. In particular examples, the gate contact 163 may be located vertically above the active semiconductor layers 108 of nanosheet stack 103 within channel cell 129, the gate contact 163 may be located vertically above the active semiconductor layers 108 of nanosheet stack 105 within channel cell 127, the gate contact 163 may be located vertically above both the WF gate 132 and the WF gate 142 at the interface or boundary of channel cell 127 and channel cell 129.

In some implementations, the formation of gate contact 163 may be a part of middle of the line (MOL) fabrication processes and semiconductor IC device 100 may be further subjected to additional back end of the line (BEOL) fabrication processes.

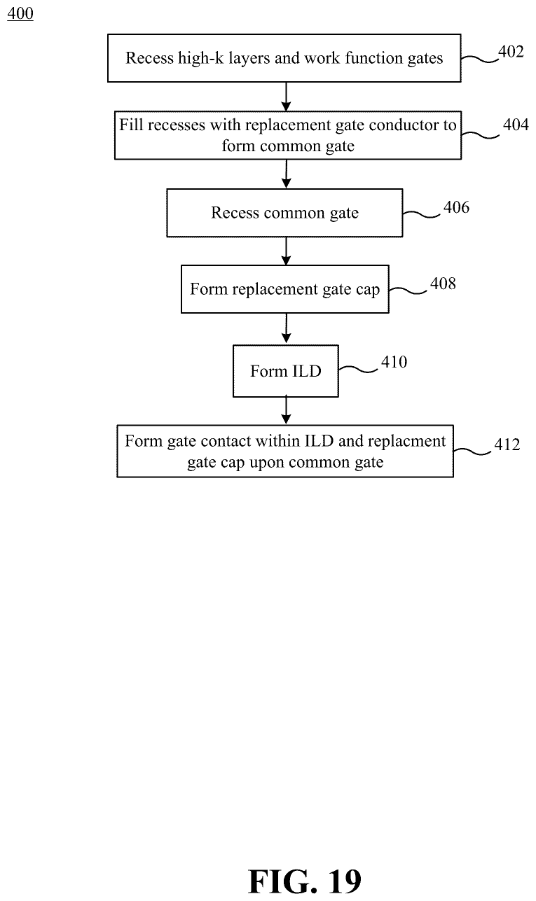

FIG. 19 depicts a method 400 of fabricating semiconductor IC device 100 that includes relatively different work function gates (i.e., WF gate 132 and WF gate 142) within the replacement gate structure, according to embodiments. In some implementations, method 400 may be a continuation of method 300. Method 400 may begin, at block 402, with partially recessing high-K layer 130, WF gate 132, high-K layer 140, WF gate 142, and/or the interfacial layers associated therewith to form at least opening 152 between conductive fill gate 132 and conductive fill gate 142. The high-K layer 130, WF gate 132, high-layer 140, WF gate 142, and/or the interfacial layers associated therewith may further be partially recessed to further opening 150 and/or opening 154.

Method 400 may continue, at block 404, with depositing a conductor within the opening(s) 152, 150, and/or 154. The deposited material may be the same material relative to one or both materials of conductive fill gate 132 and conductive fill gate 142. The deposited conductor within opening 152 effectively melds conductive fill gate 132 and conductive fill gate 142 and forms common conductive gate 156.

Method 400 may continue, at block 406, with recessing the common conductive gate 156 and, at block 408, with forming replacement gate cap 158 upon the common conductive gate 156 within the recess.

Method 400 may continue, at block 410, with forming ILD 160 upon the top surface of ILD 126, spacer 120, replacement gate cap 158, or the like and, at block 412, with forming a gate contact within ILD 160 and upon the common conductive gate 156.

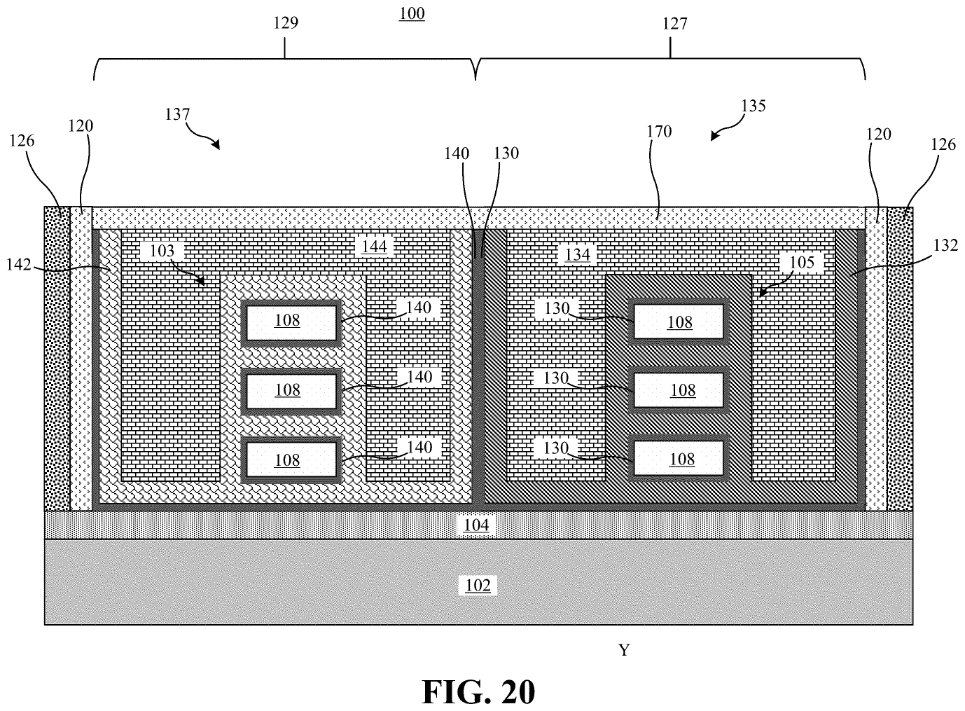

Referring now to FIG. 20, this figure depicts cross-sectional views of the semiconductor IC device 100, depicted in FIG. 12, after additional fabrication operations where the replacement gate structures 135, 137 are recessed and a replacement gate cap 170 is formed. The replacement gate structures 135, 137 may be recessed by etching techniques. After the recessing of replacement gate structures 135, 137, a void above the replacement gate structures 135, 137 between the spacer 120 is formed. The dry and wet etching processes can have etching parameters that can be tuned, such as etchants used, etching temperature, etching solution concentration, etching pressure, source power, RF bias voltage, RF bias power, etchant flow rate, exposure time, and other suitable parameters so as to achieve the predetermined depth of partial removal of replacement gate structures 135, 137. In a particular implementation, as depicted, replacement gate structures 135, 137 is recessed to a depth so as to retain at least some of the conductor of conductor fill gates 134, 144 vertically above nanosheet stack 103, 105, respectively.

Subsequently, the replacement gate cap 170 may be formed within the void. The replacement gate cap 170 can be deposited by any suitable techniques, such as ALD, CVD, PVD, thermal oxidation, combinations thereof, or other suitable techniques. The replacement gate cap 170 material may be dielectric material, such as silicon nitride, SiBCN, SiNC, SIN, SiCO, SiNOC, a combination thereof, or the like, and can include a single material layer or different material layers. After the formation of replacement gate cap 170, the top surface of the semiconductor IC device 100 may be planarized by a planarization technique such as a CMP.

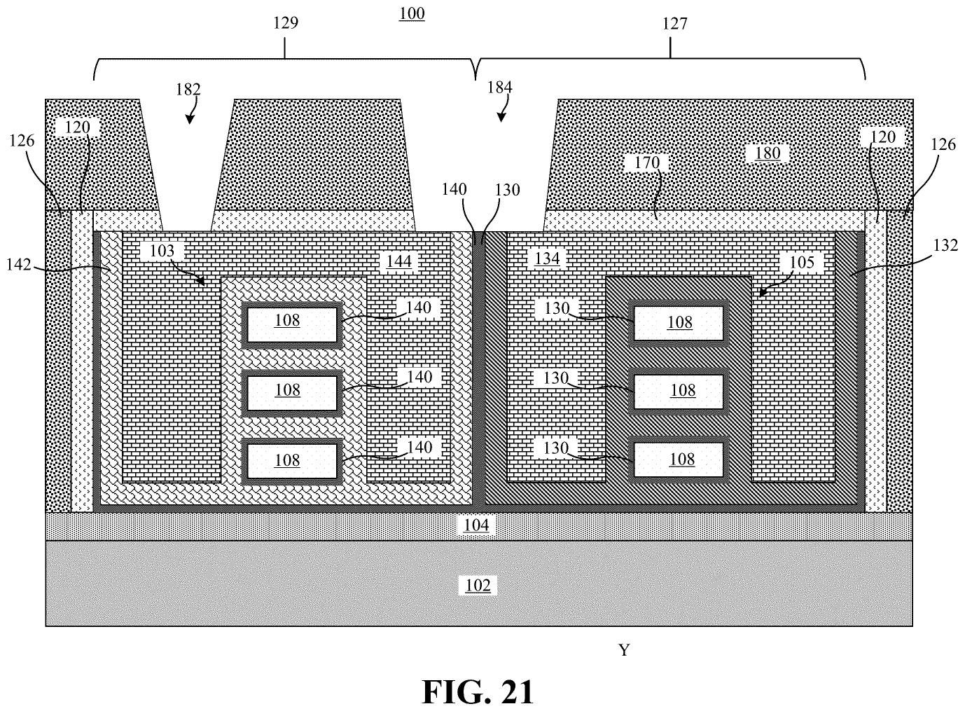

Referring now to FIG. 21, this figure is a cross-sectional view of semiconductor IC device 100 after additional fabrication operations, where ILD 180 is formed and gate contact opening 184 is formed. In some implementations, an optional additional gate contact opening 182 is also formed. However, additional gate contact opening may not be needed depending on circuit design.

The ILD 180 may be formed upon the top surface of ILD 126, spacer 120, replacement gate cap 170, or the like. The ILD 180 may be formed by depositing a dielectric material, such as, for example, porous silicates, carbon doped oxides, silicon dioxides, silicon nitrides, silicon oxynitrides, or other dielectric materials. Any known manner of forming the ILD 180 can be utilized. The ILD 180 can be formed using, for example, CVD, PECVD, ALD, flowable CVD, spin-on dielectrics, or PVD.

Subsequently, gate contact opening(s) 182, 184 are formed within ILD 180. The formation of gate contact opening(s) 182, 184 may include etching the ILD 180 to form the opening(s). The gate contact opening 184 may expose both conductive fill gate 134 and conductive fill gate 144, may expose both WF gate 132 and WFM gate 142, and may expose both high-k layer 130 and high-layer 140 and the interfacial layer(s) associated therewith. In an example, gate contact opening 184 may be horizontally centered at the interface or boundary of both channel cell 127 and channel cell 129.

The gate contact opening 182 may expose conductive fill gate 144 when gate contact opening 182 is located within channel cell 129 or may expose conductive fill gate 134 when gate contact opening 182 is located within channel cell 127. In particular examples, the gate contact opening 182 may be located vertically above the active semiconductor layers 108 of nanosheet stack 103 within channel cell 129, the gate contact opening 182 may be located vertically above the active semiconductor layers 108 of nanosheet stack 105 within channel cell 127, and the gate contact opening 184 may be located vertically above the interface or boundary of channel cell 127 and channel cell 129.

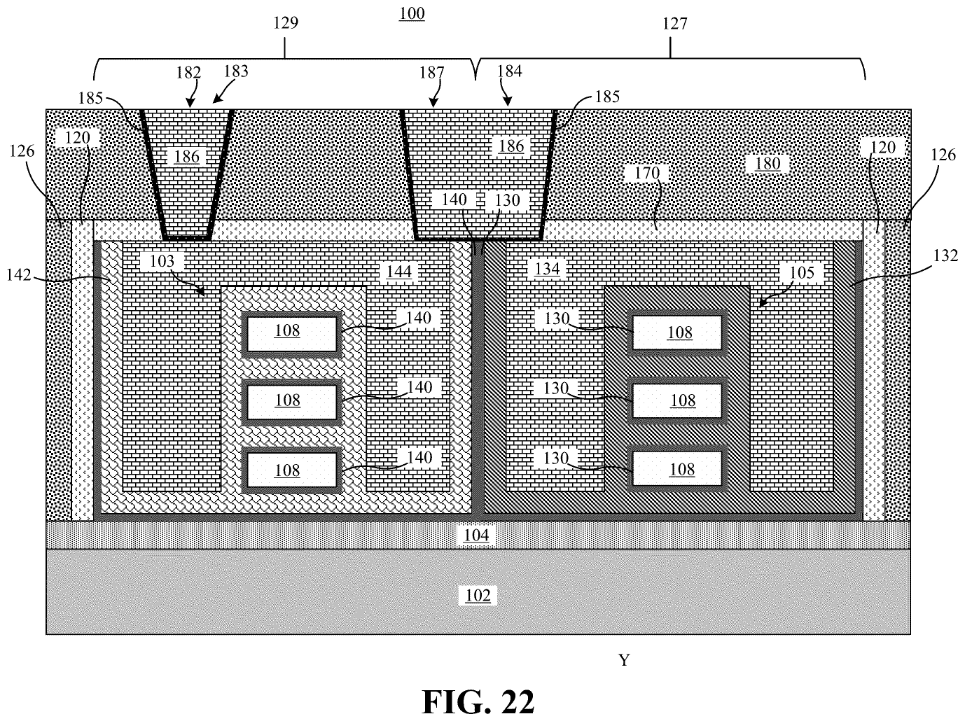

Referring now to FIG. 22, this figure is a cross-sectional view of semiconductor IC device 100 after additional fabrication operations wherein a gate contact 187 is formed in gate contact opening 184. In implementations, wherein gate contact opening 184 is present, a gate contact 183 may further be formed therein. The formation of the gate contact(s) 187, 183 may include etching the ILD 180 to form the gate contact opening(s) 184, 182 therein, forming a blanket conductive barrier layer extending into the gate contact opening 162, depositing a metallic or conductive material over the blanket conductive barrier layer, and performing a planarization process, such as a CMP process or a mechanical grinding process, to remove excess portions of the conductive barrier layer and the conductive material. Gate contact(s) 187, 183 may consist of a liner 185 formed of Ni, NiPt, Ti, TiN, TaN, etc. and a conductive or metal fill 186 deposited thereupon, such as Al, Ru, W, Co, Cu, etc.

The gate contact 187 may contact or otherwise meld to the exposed conductive fill gate 134 and conductive fill gate 144, to the exposed WF gate 132 and MFM gate 142, and to the exposed high-k layer 130 and high-K layer 140 and the interfacial layer(s) associated therewith. The gate contact 183 may contact or otherwise meld to the exposed conductive fill gate 134 or to the exposed conductive fill gate 144, depending upon the location of gate contact opening 182.

In some implementations, the formation of gate contact(s) 187, 183 may be a part of middle of the line (MOL) fabrication processes and semiconductor IC device 100 may be further subjected to additional back end of the line (BEOL) fabrication processes.

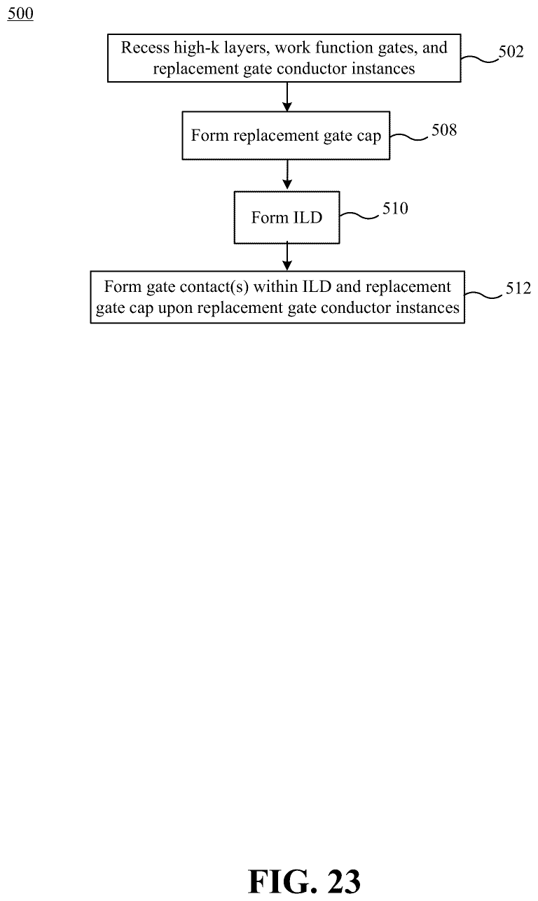

FIG. 23 depicts a method 500 of fabricating semiconductor IC device 100 that includes relatively different work function gates (i.e., WF gate 132 and WF gate 142) within the replacement gate structure, according to embodiments. In some implementations, method 500 may be a continuation of method 300. Method 500 may begin, at block 502, with recessing high-K layer 130, recessing WF gate 132, recessing high-K layer 140, recessing WF gate 142, recessing the interfacial layers associated therewith (if present), recessing conductive fill gate 134, and recessing conductive fill gate 144. In other words, replacement gate structures 135, 137 are recessed.

Method 500 may continue, at block 508, with forming replacement gate cap 170 upon the replacement gate structures 135, 137 within the spacer 120. Method 500 may continue, at block 510, with forming ILD 180 upon the top surface of ILD 126, spacer 120, replacement gate cap 170, or the like and, at block 512, with forming a gate contact 187 within ILD 160 upon the conductive fill gate 134 and upon the conductive fill gate 144.

For clarity, the semiconductor IC device 100 may include a p-type transistor (e.g., transistor associated with active semiconductor layers 108 in nanosheet stack 105) and a n-type transistor (e.g., transistor associated with active semiconductor layers 108 in nanosheet stack 103). The p-type transistor includes a first plurality of nanosheets (i.e., semiconductor layers 108 in nanosheet stack 105) surrounded by a first work (WF) gate (e.g., WF gate 132) that includes a first vertical WF gate portion (e.g., vertical portion of WF gate 132 associated with high-k layer 130 at the junction of channel cells 127, 129). The n-type transistor includes a second plurality of nanosheets (i.e., semiconductor layers 108 in nanosheet stack 105) surrounded by a second WF gate (e.g., WF gate 142) that includes a second vertical WF gate portion adjacent to the first vertical WF gate portion at a junction between the p-type transistor and the n-type transistor (e.g., vertical portion of WF gate 142 associated with high-K layer 140 at the junction of channel cells 127, 129). The n-type transistor and the p-type transistor share a common gate (e.g., common gate 156) upon the first WF gate and upon the second WF gate.

In an example, the first WF gate, the second WF gate, and the common gate are between a shared gate spacer (e.g., spacer 120). In an example, a vertical high-K layer (e.g., vertical high-K layer formed from high-K layer 130 and high-K layer 140 at the interface of channel cells 127 and 129) is between the second vertical WF gate portion and the first vertical WF gate portion at the junction between the p-type transistor and the n-type transistor.

In an example, a first high-k layer (e.g., high-k layer 130 or high-K layer 140) is between the first WF gate and the first plurality of nanosheets. In this example, a second high-k layer (high-K layer 140 or high-K layer 143) is between the second WF gate and the second plurality of nanosheets.

In an example, a thickness of the vertical high-K layer (vertical high-K layer formed from high-K layer 130 and high-K layer 140 at the interface of channel cells 127 and 129) is equal to a sum of a thickness of the first high-k layer and a thickness of the second high-K layer (e.g., high-K layer 130 or high-K layer 140 around active semiconductor layers 108). In another example, a thickness of the vertical high-k layer can be the thickness of high-K layer 140 if high-K layer 130 is removed from the sidewall during removal of sacrificial gate from the channel region 129.

For clarity, the semiconductor IC device 100 may include a first plurality of nanosheets (e.g., active semiconductor layers 108 of nanosheet stack 105) surrounded by a first work function (WF) gate (e.g., WF gate 132), the first WF gate comprising a first vertical WF gate portion (e.g., portion of WF gate 132 associated with high-K layer 130 at the junction of channel cell 127 and channel cell 129). The semiconductor IC device 100 may include a second plurality of nanosheets (e.g., active semiconductor layers 108 of nanosheet stack 103) surrounded by a second WF gate (e.g., WF gate 142) that includes a second vertical WF gate portion (e.g., portion of WF gate 132 associated with high-layer 140 at the junction of channel cell 127 and channel cell 129). The semiconductor IC device 100 may include a vertical high-K layer (e.g., combined high-K layer 130 and high-K layer 140) in contact with and between the first vertical WF gate portion and the second vertical WF gate portion. The semiconductor IC device 100 may include a first conductive gate (e.g., conductive fill gate 134) upon the first WF gate and a second conductive gate (e.g., conductive fill gate 144) upon the second WF gate.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor IC device comprising:
a p-type transistor comprising a first plurality of nanosheets surrounded by a first work function (WF) gate, the first WF gate comprising a first vertical WF gate portion;
a n-type transistor comprising a second plurality of nanosheets surrounded by a second WF gate, the second WF gate comprising a second vertical WF gate portion adjacent to the first vertical WF gate portion at a junction between the p-type transistor and the n-type transistor; and
a common gate upon the first WF gate and upon the second WF gate.

2. The semiconductor IC device of claim 1, wherein the first WF gate, the second WF gate, and the common gate are between a shared gate spacer.

3. The semiconductor IC device of claim 1, wherein a vertical high-K layer is between the second vertical WF gate portion and the first vertical WF gate portion at the junction between the p-type transistor and the n-type transistor.

4. The semiconductor IC device of claim 3, wherein a first high-k layer is between the first WF gate and the first plurality of nanosheets and wherein a second high-K layer is between the second WF gate and the second plurality of nanosheets.

5. The semiconductor IC device of claim 4, wherein a thickness of the vertical high-layer is equal to or less than a sum of a thickness of the first high-K layer and a thickness of the second high-K layer.

6. The semiconductor IC device of claim 2, wherein top surfaces of the first vertical WF gate portion and the second vertical WF gate portion is below a top surface of the common gate at the junction between the p-type transistor and the n-type transistor.

7. The semiconductor IC device of claim 2, further comprising:
a replacement gate cap upon the common gate;
an interlayer dielectric (ILD) upon the replacement gate cap; and
a gate contact within the ILD and within the replacement gate cap connected to the common conductive gate.

8. A semiconductor IC device comprising:
a first plurality of nanosheets surrounded by a first work function (WF) gate, the first WF gate comprising a first vertical WF gate portion;
a second plurality of nanosheets surrounded by a second WF gate, the second WF gate comprising a second vertical WF gate portion;
a vertical high-K layer in contact with and between the first vertical WF gate portion and the second vertical WF gate portion;
a first conductive gate upon the first WF gate; and
a second conductive gate upon the second WF gate.

9. The semiconductor IC device of claim 8, wherein the first vertical WF gate portion, the vertical high-K layer, and the first vertical WF gate portion separate the first conductive gate from the second conductive gate.

10. The semiconductor IC device of claim 8, wherein the first WF gate, the vertical high-K layer, the second WF gate, the first conductive gate, the second conductive gate are between a shared gate spacer.

11. The semiconductor IC device of claim 10, wherein a first high-K layer is between the first WF gate and the first plurality of nanosheets and wherein a second high-K layer is between the second WF gate and the second plurality of nanosheets.

12. The semiconductor IC device of claim 11, wherein a thickness of the vertical high-K layer is equal to or less than a sum of a thickness of the first high-K layer and a thickness of the second high-K layer.

13. The semiconductor IC device of claim 8, further comprising:
a replacement gate cap upon the first WF gate, the vertical high-K layer, the second WF gate, the first conductive gate, and the second conductive gate;
an interlayer dielectric (ILD) upon the replacement gate cap; and
a gate contact within the ILD and within the replacement gate cap, the gate contact connected to the first conductive gate and to the second conductive gate.

14. The semiconductor IC device of claim 8, further comprising:
a gate contact connected to the first conductive gate and to the second conductive gate.

15. The semiconductor IC device of claim 14, wherein the gate contact is further connected to the first vertical WF gate portion and to the second vertical WF gate portion.

16. A replacement gate structure within a gate spacer, the replacement gate structure comprising:
a first high-K layer around one or more first channel(s) that are covered by the replacement gate structure;
a second high-K layer comprising around one or more second channel(s) that are covered by the replacement gate structure;
a first work function (WF) gate upon the first high-k layer; and
a second WF gate upon the second high-layer.

17. The replacement gate structure of claim 16, further comprising:
a first conductive gate upon the first WF gate; and
a second conductive gate upon the second WF gate.

18. The replacement gate structure of claim 16, further comprising:
a common conductive gate upon the first WF gate and upon the second WF gate.

19. The replacement gate structure of claim 17, wherein the first WF gate comprises a first vertical WF portion and a first channel WF portion around the one or more first channel(s) and wherein the second WF gate comprises a second vertical WF portion and a second channel WF portion around the one or more second channel(s).

20. The replacement gate structure of claim 19, wherein the first vertical gate WF portion, the first vertical high-K portion, the second vertical WF gate portion, and the second vertical high-k portion separate the first conductive gate from the second conductive gate.
